(19) United States
(12) Patent Application Publication
(10) Pub. No.: US 2016/0005674 A1
(43) Pub. Date: Jan. 7, 2016

(54) INTEGRATED CIRCUIT ASSEMBLY AND INTEGRATED CIRCUIT PACKAGING STRUCTURE

(71) Applicant: RICHTEK TECHNOLOGY CORP, Hsinchu (TW)

(72) Inventors: Ya Tzu WU, Hsinchu (TW); Yu Lin Yang, Hsinchu (TW)

(21) Appl. No.: 14/520,354

(22) Filed: Oct. 22, 2014

(30) Foreign Application Priority Data
Jul. 4, 2014 (TW) 103123104

(51) Int. Cl. H01L 23/367; H01L 23/495; H01L 23/31; H01L 23/00

(52) U.S. Cl. CPC H01L 23/367; H01L 24/13; H01L 23/495; H01L 23/3114

(57) ABSTRACT

An integrated circuit packaging structure includes a chip, an electrical bump, a heat dissipation bump, a lead frame, and a sealant. The chip includes an active surface and an electronic component that is formed by using a semiconductor process. The electrical bump is electrically connected to the electronic component through the active surface. The heat dissipation bump is connected to the active surface. The lead frame is electrically connected to the electrical bump. The sealant covers the chip, the lead frame, and the electrical bump, wherein the heat dissipation bump and a part of the lead frame are exposed without being covered. The height of the heat dissipation bump relative to the active surface is unequal to that of the electrical bump relative to the active surface.

### CROSS REFERENCE TO RELATED APPLICATIONS

This non-provisional application claims priority claim under 35 U.S.C. §119(a) on Patent Application No. 103123104 filed in Taiwan, R.O.C. on Jul. 4, 2014, the entire contents of which are hereby incorporated by reference herein.

### BACKGROUND

1. Technical Field

This disclosure relates to an integrated circuit assembly and an integrated circuit packaging structure, and in particular, to an integrated circuit assembly applicable to a heat-dissipation flip-chip packaging structure and an integrated circuit packaging structure.

2. Related Art

Current electronic products need to have high-speed operation and processing capabilities for powerful functions. Moreover, electronic products gradually decrease in size for the purpose of portability. Therefore, the density of arranging electronic components in an apparatus becomes high, causing a challenge of heat dissipation design. During fabrication of an integrated circuit, chip-scale packaging (CSP) is an integrated circuit packaging technology developed to adapt to reduced sizes of electronic products, where flip-chip packaging is a packaging technology that is very popular nowadays.

Refer to ROC Invention Patent 1254433 (referred to as Prior Art I below). Prior Art I discloses a heat dissipation flip-chip apparatus, which has a chip, where a bump is formed on an active surface of the chip, and the chip is then connected to an external solder ball through a lead on a substrate. Moreover, a rear surface of the chip is connected to a heat sink to provide a main heat dissipation path. Because a heat sink of the heat dissipation flip-chip apparatus disclosed in Prior Art I is stacked above the chip, it becomes difficult to achieve an objective of a thin integrated circuit, and an objective of reducing the height of the apparatus is limited.

Refer to ROC Invention Patent 1283447 (referred to as Prior Art II below). Prior Art II discloses a flip-chip thin film packaging structure, which has a flip-chip chip disposed on an upper surface of a flexible substrate, and has a heat sink disposed on a lower surface of the flexible substrate, where the flip-chip chip is connected to the heat sink through a heat conducting through hole passing through the upper surface and the lower surface of the flexible substrate. According to the disclosure in Prior Art II, the heat sink can be disposed on the flexible substrate in a sputtering manner. Because a metal layer formed in a sputtering manner may be very thin and can reach an order of magnitude of micro-meter (um), compared with Prior Art I, further improvement can be made in terms of the height of the flip-chip packaging in Prior Art II. However, through analysis from the structure of the flip-chip chip, the flip-chip chip can only reach an exposed heat sink after at least passing through heterogeneous materials such as a lead layer and a heat conducting through hole; moreover, the size of the heat conducting through hole is limited to some extent; these factors affect the heat dissipation efficiency of the flip chip packaging structure disclosed in Prior Art II.

### SUMMARY

To solve the foregoing problem, this disclosure provides an integrated circuit assembly and an integrated circuit packaging structure, and in particular, to an integrated circuit assembly applicable to a heat-dissipation flip-chip packaging structure and an integrated circuit packaging structure.

This disclosure provides an integrated circuit assembly, including a chip, an electrical bump, and a heat dissipation bump. The chip has an active surface and an electronic component that is formed by using a semiconductor process. The electrical bump is electrically connected to the electronic component through the active surface. The heat dissipation bump is connected to the active surface. The height of the heat dissipation bump relative to the active surface is unequal to that of the electrical bump relative to the active surface.

Moreover, this disclosure further provides an integrated circuit packaging structure, including a chip, an electrical bump, a heat dissipation bump, a lead frame, and a sealant. The chip includes an electronic component formed by using a semiconductor process and an active surface. The electrical bump is electrically connected to the electronic component through the active surface. The heat dissipation bump is connected to the active surface. The lead frame includes a lead, and the lead is electrically connected to the electrical bump. The sealant covers the chip, the lead frame, and the electrical bump, and the heat dissipation bump and a part of the lead frame are exposed without being covered. The height of the heat dissipation bump relative to the active surface is unequal to that of the electrical bump relative to the active surface.

In the integrated circuit assembly and the integrated circuit packaging structure disclosed in this disclosure, a connection relationship between a heat dissipation bump and a chip forms a direct heat dissipation path to the exterior, and therefore, desirable heat dissipation efficiency is achieved in combination with design of an external heat dissipation mechanism. Moreover, the structure of the integrated circuit packaging structure disclosed in this disclosure is simplified, so that the height of the integrated circuit packaging structure can be further lowered, which helps to make an application apparatus of the integrated circuit packaging structure thin; therefore, the integrated circuit packaging structure is very applicable to a portable electronic apparatus.

Features, implementation, and efficacy of the optimal embodiments of the present creation are described below in detail with reference to the accompanying drawings.

### BRIEF DESCRIPTION OF THE DRAWINGS

The disclosure will become more fully understood from the detailed description given herein below for illustration only, and thus are not limitative of the disclosure, and wherein:

FIG. 1 is a schematic sectional view of an integrated circuit assembly according to this disclosure;

FIG. 2 is a schematic sectional view of an integrated circuit packaging structure according to an embodiment of this disclosure;

FIG. 3 is a schematic sectional view of an integrated circuit packaging structure according to another embodiment of this disclosure; and

FIG. 4 is a top perspective view of an integrated circuit packaging structure according to this disclosure.

### DETAILED DESCRIPTION

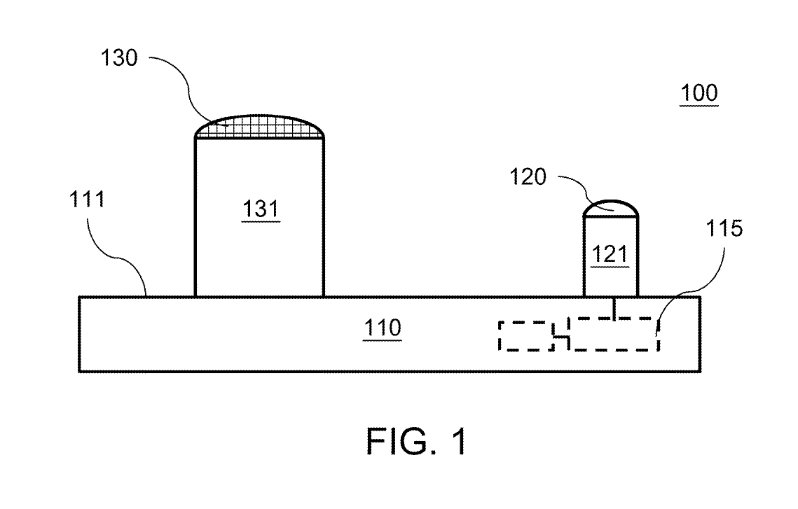

FIG. 1 is a schematic sectional view of an integrated circuit assembly 100 according to this disclosure. The integrated circuit assembly 100 includes a chip 110, an electrical bump 120, and a heat dissipation bump 130. The chip 110 has an active surface 111 and an electronic component 115 that is formed by using a semiconductor process. The electrical bump 120 is electrically connected to the electronic component 115 through the active surface 111. The heat dissipation bump 130 is connected to the active surface 111. The height of the heat dissipation bump 130 relative to the active surface 111 is unequal to that of the electrical bump 120 relative to the active surface 111.

The integrated circuit assembly 100 disclosed by this disclosure is applicable to a flip-chip packaging structure introduced subsequently, so that a formed integrated circuit package has advantages of a low height and desirable heat dissipation. The chip 110 is an integrated circuit chip formed by using any semiconductor process, and can include any active component such as a field-effect transistor (FET) and a bipolar junction transistor (BJT), or include any passive component such as a resistor, a capacitor, an inductor, and a diode. The electrical bump 120 is used for transferring an electrical signal, so that a circuit on the chip 110 can electrically communicate with an external circuit. The heat dissipation bump 130 is used as a heat dissipation path for the chip 110, so that a working heat source generated by the chip 110 can be effectively dissipated outside by using the heat dissipation bump 130.

In addition, to make heat dissipation of the integrated circuit assembly 100 more efficient, the height of the heat dissipation bump 130 relative to the active surface 111 is unequal to that of the electrical bump 120 relative to the active surface 111. For example, in the embodiment disclosed in FIG. 1, the height or distance from the heat dissipation bump 130 to the active surface 111 is greater than the height or distance from the electrical bump 120 to the active surface 111. In this case, when a flip-chip packaging structure of the integrated circuit assembly 100 is formed, the heat dissipation bump 130 is directly exposed from a surface of the packaging structure, and is connected to a heat dissipation mechanism designed in the exterior of the flip-chip package, so that a heat sink can be arranged in parallel with the integrated circuit assembly 100 on a circuit board, and the thickness of the whole electronic apparatus is further reduced.

To make the height (or distance) of the heat dissipation bump 130 relative to the active surface 111 different from that of the electrical bump 120 relative to the active surface 111, the heat dissipation bump 130 can be connected to the active surface 111 of the chip 110 through a heat conductor 131, and the electrical bump 120 can be connected to the active surface 111 through an electrical conductor 121. The heat conductor 131 is formed by a material, such as metal, having desirable heat conductivity. The electrical conductor 121 is formed by a material, such as metal, having desirable heat conductivity. A height difference formed by the heat conductor 131 and the electrical conductor 121 can make the height (or distance) of the heat dissipation bump 130 relative to the active surface 111 different from that of the electrical bump 120 relative to the active surface 111. Because the heat conductor 131 and the heat dissipation bump 130 directly form a heat dissipation path to the exterior for the chip 110, desirable heat dissipation efficiency is provided. The heat conductor 131 and the electrical conductor 121 can be formed by using methods such as etching, sputtering, exposure and development known in a general semiconductor process, which can be implemented and accomplished by persons of ordinary skill in the art according to requirements of applications by using the known technologies in the art after fully understanding the spirit disclosed in this disclosure and is therefore no longer elaborated herein.

In addition, in yet another embodiment of this disclosure, the heat dissipation bump 130 and the electrical bump 120 can also be directly connected to the active surface 111 of the chip 110; the heat dissipation bump 130 and the electrical bump 120 are different in volume, so that the height of the heat dissipation bump 130 may be formed different from that of the electrical bump 120. For example, the volume of the heat dissipation bump 130 is greater than that of the electrical bump 120, so that the height of the heat dissipation bump 130 relative to the active surface 111 is made different from that of the electrical bump 120 relative to the active surface 111.

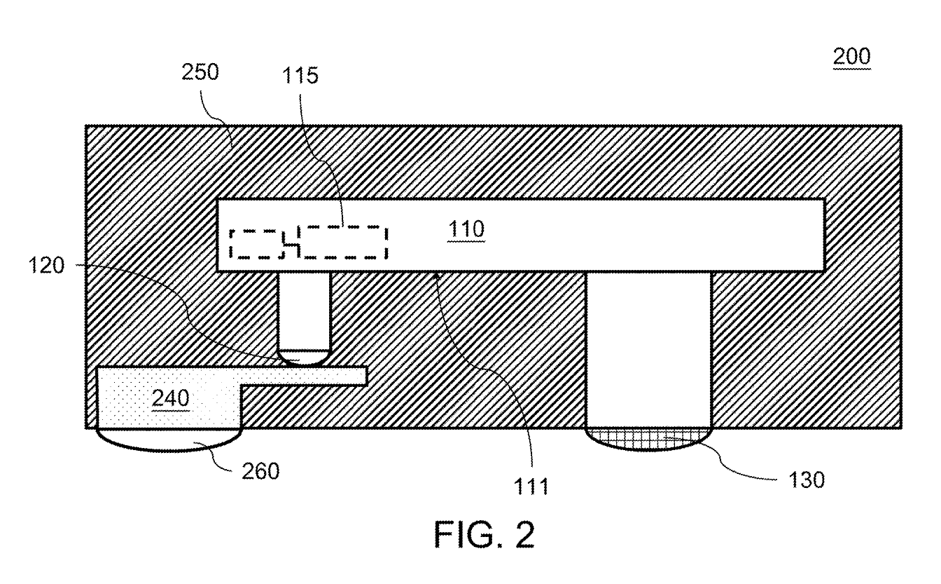

FIG. 2 is a schematic sectional view of an integrated circuit packaging structure 200 according to an embodiment of this disclosure. The integrated circuit packaging structure 200 includes a chip 110, an electrical bump 120, a heat dissipation bump 130, a lead frame 240, and a sealant 250. The chip 110 includes an electronic component 115 formed by using a semiconductor process and an active surface 111. The electrical bump 120 is electrically connected to the electronic component 115 through the active surface 111. The heat dissipation bump 130 is connected to the active surface 111. The lead frame 240 is electrically connected to the electrical bump 120. The sealant 250 covers the chip 110, the lead frame 240, and the electrical bump 120, and the heat dissipation bump 130 and a part of the lead frame 240 are exposed without being covered. The height of the heat dissipation bump 130 relative to the active surface 111 is unequal to that of the electrical bump 120 relative to the active surface 111.

A structure formed by the chip 110, the electrical bump 120, and the heat dissipation bump 130 is the integrated circuit assembly 100 disclosed in FIG. 1. The sealant 250 can be formed by using a method of, for example, molding, and is used for protecting the chip 110 from moisture, oxidization or direct collision, and makes the chip 110, the electrical bump 120, the heat dissipation bump 130, and the lead frame 240 form an integrated structure.

In addition, in yet another embodiment of this disclosure, the integrated circuit packaging structure 200 may further include an external bump 260 connected to the part, exposed from the sealant 250, of the lead frame 240. The external bump 260 can be used to be electrically connected to an external circuit conveniently in a manner of, for example, welding, so that a circuit on the chip 110 can electrically communicate with the external circuit.

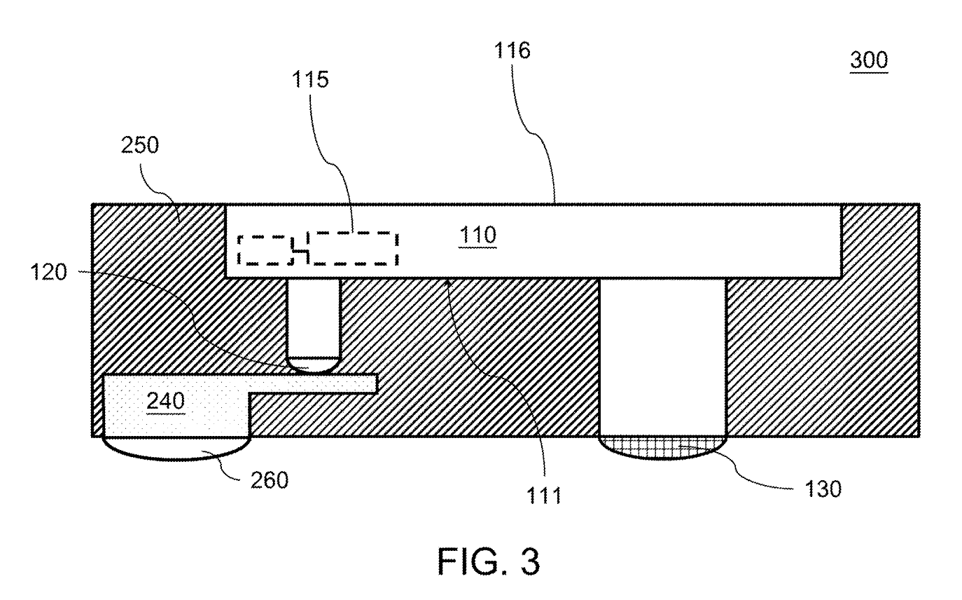

In yet another embodiment of this disclosure, the lead frame 240 of the integrated circuit packaging structure 200 includes a lead layer 245 (shown in FIG. 3).

FIG. 3 is a schematic sectional view of an integrated circuit packaging structure 300 according to another embodiment of this disclosure. A difference between the integrated circuit packaging structure 300 and the integrated circuit packaging structure 200 shown in FIG. 2 lies in that, in the integrated circuit packaging structure 300, the chip 110 has a rear surface 116 opposite the active surface 115, and the rear surface 116 is exposed from the sealant 250. The rear surface 116 of the chip 110 is exposed from the sealant 250, which makes it convenient to further add a heat sink outside the integrated circuit packaging structure 300, thereby enhancing a heat dissipation function and therefore helping miniaturization of a high-power circuit application.

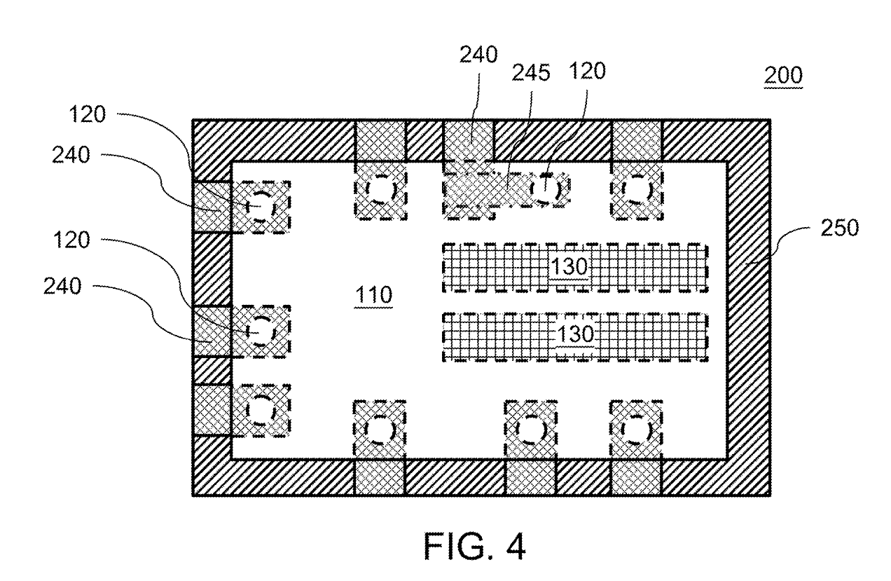

FIG. 4 is a top perspective view of an integrated circuit packaging structure 200 according to this disclosure. In this embodiment, an electrical bump 120 can be separately connected to a group of lead frames 240, and the electrical bump 120 can be directly connected to the lead frame 240, or electrically connected to the lead frames 240 through a lead layer 245. A heat dissipation bump 130 can be made at a part of the bottom, not overlapped by the lead frame 240, of the integrated circuit packaging structure 200, so as to form a heat conducting path. The heat dissipation bump 130 can be made in various shapes according to capabilities of process technologies, for example, made in a square shape. It should be noted that, the structure disclosed in FIG. 4 is only used for explaining the spirit of this disclosure, and is not intended to limit the scope of this disclosure. Persons of ordinary skill in the art can make different design, such as arrangement design of the external bump 260 and multiple electrical bumps 120 sharing a same lead frame 240, according to requirements of an application after fully understanding the spirit of this disclosure, which is therefore no longer elaborated herein.

In the integrated circuit packaging structure 200 disclosed in this disclosure, a connection relationship between a heat dissipation bump 130 and a chip 110 forms a direct heat dissipation path to the exterior, and therefore, desirable heat dissipation efficiency is achieved in combination with design of an external heat dissipation mechanism. Moreover, the structure of the integrated circuit packaging structure 200 is simplified, and a substrate component in a conventional flip-chip package is omitted, so that the height of the integrated circuit packaging structure 200 can be further lowered, which helps to make an application apparatus of the integrated circuit packaging structure 200 thin; therefore, the integrated circuit packaging structure 200 is very applicable to a portable electronic apparatus.

Though the embodiments of the present creation are disclosed above, the embodiments are not used for limiting the present creation; several variations can be made according to the shapes, structures, features, and quantity described in the application scope of the present creation by persons skilled in the art without departing from the spirit and scope of the present creation, and therefore, the patent protection scope of the present creation shall be as defined in the appended claims of the specification.

1. An integrated circuit assembly, comprising:
a chip, including an active surface and an electronic component that is formed by using a semiconductor process;
a heat conductor, formed by using the semiconductor process, and protruding on the active surface;
an electrical conductor, formed by using the semiconductor process, and protruding on the active surface;
an electrical bump, electrically connected to the active surface via the electrical conductor, so as to be electrically connected to the electronic component through the active surface; and
a heat dissipation bump, connected to the active surface via the heat conductor, so as to be connected to the active surface;
wherein, through the height difference formed by the heat conductor and the electrical conductor, the height of the heat dissipation bump relative to the active surface is higher than that of the electrical bump relative to the active surface.

2. (canceled)

3. (canceled)

4. (canceled)

5. The integrated circuit assembly as claimed in claim 1, wherein the volume of the heat dissipation bump is greater than that of the electrical bump.

6. (canceled)

7. The integrated circuit assembly as claimed in claim 1, wherein materials of the heat conductor and the electrical conductor are metal.

8. An integrated circuit packaging structure, comprising:
a chip, having an active surface and an electronic component that is formed by using a semiconductor process;
a heat conductor, formed by using the semiconductor process, and protruding on the active surface;
an electrical conductor, formed by using the semiconductor process, and protruding on the active surface;
an electrical bump, electrically connected to the electrical conductor, so as to be electrically connected to the electronic component through the active surface; and
a heat dissipation bump, connected to the heat conductor, so as to be connected to the active surface;
a lead frame, electrically connected to the electrical bump; and
a sealant, covering the chip, the lead frame, and the electrical bump, wherein the heat dissipation bump and a part of the lead frame are exposed without being covered;
wherein, through the height difference formed by the heat conductor and the electrical conductor, the height of the heat dissipation bump relative to the active surface is higher than that of the electrical bump relative to the active surface.

9. The integrated circuit packaging structure as claimed in claim 8, wherein the volume of the heat dissipation bump is greater than that of the electrical bump.

10. The integrated circuit packaging structure as claimed in claim 8, further comprising an external bump connected to the part, exposed from the sealant, of the lead frame.

11. The integrated circuit packaging structure as claimed in claim 8, wherein the chip has a rear surface opposite the active surface, and the rear surface is exposed from the sealant.

12. The integrated circuit packaging structure as claimed in claim 9, wherein the chip has a rear surface opposite the active surface, and the rear surface is exposed from the sealant.

13. (canceled)

14. (canceled)

15. (canceled)

16. (canceled)

17. (canceled)
